(19) United States
(12) Patent Application Publication
(10) Pub. No.: US 2009/0202708 A1
(43) Pub. Date: Aug. 13, 2009

(54) Apparatus for Manufacturing Light Emitting Elements and Method of Manufacturing Light Emitting Elements

(76) Inventors: Kazuki Moyama, Hyogo (JP); Yasushi Yagi, Hyogo (JP); Toshihisa Nozawa, Hyogo (JP); Tadahiro Ohmi, Miyagi (JP); Chuichi Kawamura, Aichi (JP); Kimihiko Yoshino, Aichi (JP)

Correspondence Address: IPUSA, P.L.L.C, 1054 31ST STREET, N.W., Suite 400, Washington, DC, 20007, US

(21) Appl. No.: 12/304,324

(22) PCT Filed: Jun. 13, 2007
(86) PCT No.: PCT/JP2007/061925

§ 371 Date: Jan. 26, 2009

(30) Foreign Application Priority Data
Jun. 14, 2006 (JP) 2006-164966

(51) Int. Cl. B05D 5/06; C23C 16/54

(52) U.S. Cl. 427/66; 118/719

(57) ABSTRACT

An apparatus of manufacturing a light emitting element having a plurality of layers including an organic layer on a substrate to be processed is disclosed. The apparatus includes a plurality of process chambers to which the substrate to be processed is transferred in series, wherein the plurality of process chambers are substantially linearly connected to one another and wherein adjacent two of the process chambers are filled with gas that does not react with a layer on the substrate to be processed when the substrate to be processed is transferred between the two process chambers.

### TECHNICAL FIELD

The present invention relates to a method of manufacturing a light emitting element having an organic light emitting layer and an apparatus for manufacturing a light emitting element having an organic light emitting layer.

### BACKGROUND ART

In recent years, plat panel display devices, which can be made thinner, have been developed toward practical application, replacing cathode ray tubes (CRTs) which have long been used. For example, an organic electroluminescent element (EL element) has attracted attention because of its characteristics of self-emission, high speed response and the like. The organic EL element may be used as a plane emission element as well as the display device.

The organic EL element is configured in a manner that an organic layer including an organic EL layer (light emitting layer) is sandwiched between a positive electrode and a negative electrode. Holes are injected into the light emitting layer from the positive electrode and electrons are injected into the light emitting layer from the negative electrode, and light is emitted by recombination of the injected holes and electrons.

In the organic layer, a hole transport layer may be inserted between the positive electrode and the light emitting layer and/or an electron transport layer may be inserted between the negative electrode and the light emitting layer, when necessary, thereby improving light emission efficiency.

A general method of forming the above light emitting element is as follows. First, the organic layer is formed by an evaporation process on a substrate on which the positive electrode made of Indium Tin Oxide (ITO) is patterned. The evaporation process is to form a thin film by depositing an evaporated precursor made through evaporation or sublimation on a substrate to be processed. Next, aluminum (Al) as the negative electrode is formed on the organic layer by the evaporation process. Such a light emitting element may be referred to as a so-called top-cathode type light emitting element.

In the above manner, the light emitting element where the organic layer is formed between the positive electrode and the negative electrode is formed (see Patent Document 1).

An apparatus for manufacturing the above light emitting element is generally constructed into a so-called cluster structure in which process chambers for respectively forming the organic layer, the electrode layers, and the like are connected to a transfer chamber in different directions.

Patent Document 1: Japanese Patent Application Laid-Open Publication No. 2004-225058.

### DISCLOSURE OF THE INVENTION

### Problems to be Solved by the Invention

However, when manufacturing the light emitting element in the manufacturing apparatus having the cluster structure, a problem is caused in that such a manufacturing apparatus occupies too large a floor space (a so-called footprint).

In addition, because the cluster structure requires a plurality of the transfer chambers, depending on a process chamber configuration, there is a problem of an increased cost of the transfer mechanism including the transfer chambers, in addition to the large footprint. Moreover, a substrate transfer route becomes complicated, which causes a problem of complicated transfer control.

The present invention is generally directed to a novel and useful manufacturing apparatus and a method for manufacturing a light emitting element that are able to solve the above problems.

In addition, the present invention is specifically directed to a light emitting element manufacturing apparatus having a simplified structure and a small occupying floor space, and a light emitting element manufacturing method that requires a small occupying floor space.

### Means of Solving the Problems

A first aspect of the present invention provides an apparatus for manufacturing a light emitting element having a plurality of layers including an organic layer on a substrate to be processed. The apparatus includes a plurality of process chambers to which the substrate to be processed is transferred in series, wherein the plurality of process chambers are substantially linearly connected and wherein adjacent two of the process chambers are filled with gas that is un-reacted with a layer on the substrate to be processed when the substrate to be processed is transferred between the two process chambers.

A second aspect of the present invention provides an apparatus for manufacturing a light emitting element, according to the first aspect, wherein the gas can be changed depending on a material that constitutes the layer on the substrate to be processed.

A third aspect of the present invention provides an apparatus for manufacturing a light emitting element, according to the first or the second aspect, wherein the plurality of process chambers include at least an organic layer forming chamber for forming the organic layer, and an electrode forming chamber for forming an electrode for applying voltage to the organic layer.

A fourth aspect of the present invention provides an apparatus for manufacturing a light emitting element, according to the third aspect, wherein the organic layer includes a multilayer structure having a light emitting layer to which voltage is applied to emit light, and wherein the organic layer forming chamber is configured so that the multilayer structure may be sequentially formed by an evaporation process.

A fifth aspect of the present invention provides an apparatus for manufacturing a light emitting element, according to the fourth aspect, wherein the organic layer forming chamber is provided with a holding pedestal by which the substrate to be processed is held and provided with a plurality of film source supplying portions that supply a plurality of film sources to the substrate to be processed.

A sixth aspect of the present invention provides an apparatus for manufacturing a light emitting element, according to the fifth aspect, wherein the plurality of film source supplying portions are linearly arranged and the holding pedestal may be moved along the arrangement of the plurality of film source supplying portions.

A seventh aspect of the present invention provides an apparatus for manufacturing a light emitting element, according to any one of the fourth through the sixth aspects, wherein the plurality of process chambers include an adjusting layer forming chamber, wherein a work function adjusting layer for improving emission efficiency of the light emitting layer is formed between the organic layer and the electrode.

An eighth aspect of the present invention provides an apparatus for manufacturing a light emitting element, according to the seventh aspect, wherein the work function adjusting layer is formed of an alkali metal.

A ninth aspect of the present invention provides a method of manufacturing a light emitting element, including a plurality of process steps carried out in series in corresponding plurality of process chambers in order to form the light emitting element on a substrate to be processed, the light emitting element including a plurality of layers including an organic layer, wherein the plurality of process chambers are substantially linearly connected, and wherein adjacent two of the process chambers are filled with gas that is un-reacted with a layer on the substrate to be processed when the substrate to be processed is transferred between the two process chambers.

A tenth aspect of the present invention provides an apparatus for manufacturing a light emitting element, according to the ninth aspect, wherein the gas can be changed depending on a material that constitutes the layer on the substrate to be processed.

An eleventh aspect of the present invention provides an apparatus for manufacturing a light emitting element, according to the ninth or the tenth aspect, wherein the plurality of process steps include at least an organic layer forming step, wherein the organic layer is formed, and an electrode forming step, wherein an electrode for applying voltage to the organic layer is formed.

A twelfth aspect of the present invention provides an apparatus for manufacturing a light emitting element, according to the eleventh aspect, wherein the organic layer includes a multilayer structure having a light emitting layer to which voltage is applied to emit light, and wherein the multilayer structure may be sequentially formed by an evaporation process in the organic layer forming step.

A thirteenth aspect of the present invention provides an apparatus for manufacturing a light emitting element, according to the twelfth aspect, wherein the plurality of process steps include an adjusting layer forming step, wherein a work function adjusting layer for improving emission efficiency of the light emitting layer is formed, between the organic layer forming step and the electrode forming step.

A fourteenth aspect of the present invention provides an apparatus for manufacturing a light emitting element, according to the thirteenth aspect, wherein the work function adjusting layer is formed of an alkali metal.

### Effects of the Invention

According to an embodiment of the present invention, a light emitting element manufacturing apparatus having a simplified structure and a small occupying floor space, and a light emitting element manufacturing method that requires a small occupying floor space are provided.

### BRIEF DESCRIPTION OF THE DRAWING

FIG. 1 is a schematic view illustrating a manufacturing apparatus and a manufacturing method according to Example 1 of the present invention;

FIG. 2 is a schematic view of an example of a process chamber connected to the manufacturing apparatus shown in FIG. 1;

FIG. 3 is a schematic view of another example of a process chamber connected to the manufacturing apparatus shown in FIG. 1;

FIG. 4 is a schematic view of another example of a process chamber connected to the manufacturing apparatus shown in FIG. 1;

FIG. 5 is a schematic view of another example of a process chamber connected to the manufacturing apparatus shown in FIG. 1;

FIGS. 6(A) through 6(C) illustrate corresponding parts of the manufacturing method according to Example 1;

FIGS. 7(D) and 7(E) illustrate corresponding parts of the manufacturing method according to Example 1;

FIG. 8 is a schematic view of a manufacturing apparatus and a manufacturing method according to Example 2;

FIGS. 9(A) and 9(B) illustrate corresponding parts of the manufacturing method according to Example 2;

FIGS. 10(C) and 10(D) illustrate corresponding parts of the manufacturing method according to Example 2; and

FIGS. 11(E) and 11(F) illustrate corresponding parts of the manufacturing method according to Example 2.

### DESCRIPTION OF THE REFERENCE NUMERALS

101, 102, 103, 104, 105, 106, 107, 108, 109, 201, 202, 203, 204, 205, 206, 207, 208, 209, 210: process chamber 101A, 102A, 103A, 104A, 105A, 106A, 107A, 108A, 109A, 201A, 202A, 203A, 204A, 205A, 206A, 207A, 208A, 209A, 210a: gate valve
101A, 102A, 103A, 104A, 105A, 106A, 107A, 108A, 109A, 201A, 202A, 203A, 204A, 205A, 206A, 207A, 208A, 209A, 210A: evacuation line
1010, 102B, 103B, 1048, 105B, 106B, 107B, 108B, 109B, 201B, 202B, 2038, 2048, 205B, 2063, 2078, 208B, 2098, 210B: gas supplying line
101C, 102C, 103C, 104C, 105C, 106C, 107C, 108C, 109C, 201C, 202C, 203C, 204C, 205C, 206C, 207C, 208C, 209C, 210C: valve
101D, 102D, 103D, 104D, 105D, 106D, 107D, 108D, 109D, 201D, 2020, 203D, 204D, 205D, 206D, 207D, 2080, 209D, 210D: mass flow controller
150, 250: controller
151, 251: substrate transfer control portion
152, 252: ambient control portion
153, 253: substrate process control portion
154, 254: memory portion
155, 255: input/output portion

### BEST MODE OF CARRYING OUT THE INVENTION

According to a manufacturing apparatus (manufacturing method) of an embodiment of the present invention, a light emitting element including an organic layer including a light emitting layer is manufactured.

For example, such a light emitting element formed on a substrate made of glass or the like has an organic layer including a light emitting layer (organic EL layer) whose primary component is an organic material, which emits light when voltage is applied. In addition, two electrodes (layers) for applying voltage to the organic layer (light emitting layer) are formed on the substrate in order to oppose each other with the organic layer in-between.

The above light emitting element may be referred to as an organic EL element. This light emitting element emits light through recombination of electrons and holes when voltage is applied across the two electrodes.

Because the above light emitting element is configured with a plurality of layers stacked one on another, the light emitting element is manufactured through a plurality of processes carried out in corresponding process chambers. Therefore, manufacturing the light emitting element requires a plurality of process chambers (process apparatuses).

For example, as an example of the manufacturing apparatus having a plurality of process chambers for the light emitting element, there is a manufacturing apparatus having a cluster structure for the light emitting element. Here, in the cluster structure, the plurality of process chambers are connected to a transfer chamber for transferring the substrate to be processed. In addition, an attachment chamber where a mask is attached on the substrate to be processed, a load-lock chamber and the like may be connected to the transfer chamber, when necessary.

There are problems about the manufacturing apparatus having the cluster structure in that such an apparatus is difficult to be downsized and becomes complicated in terms of the apparatus configuration and the transfer system, which leads to another problem of increased cost of the substrate process.

A manufacturing apparatus according to an embodiment of the present invention is configured such that the plurality of process chambers are substantially linearly connected, where the substrate to be processed is transferred in series to the plurality of process chambers, so that the light emitting element is manufactured.

Namely, a plurality of processes are carried out in the corresponding process chambers connected substantially linearly, where a plurality of layers including the organic layer are formed on the substrate, so that the light emitting element is manufactured.

Therefore, the manufacturing apparatus for the light emitting element can be structurally simple and have a small occupying space (footprint). In addition, the manufacturing apparatus (manufacturing method) can provide an advantage of a simplified transfer route of the substrate to be processed and a simplified transfer system because the substrate to be processed is substantially linearly transferred.

Next, an example of the apparatus for and the method of manufacturing the light emitting element is described in reference to the accompanying drawings.

### Example 1

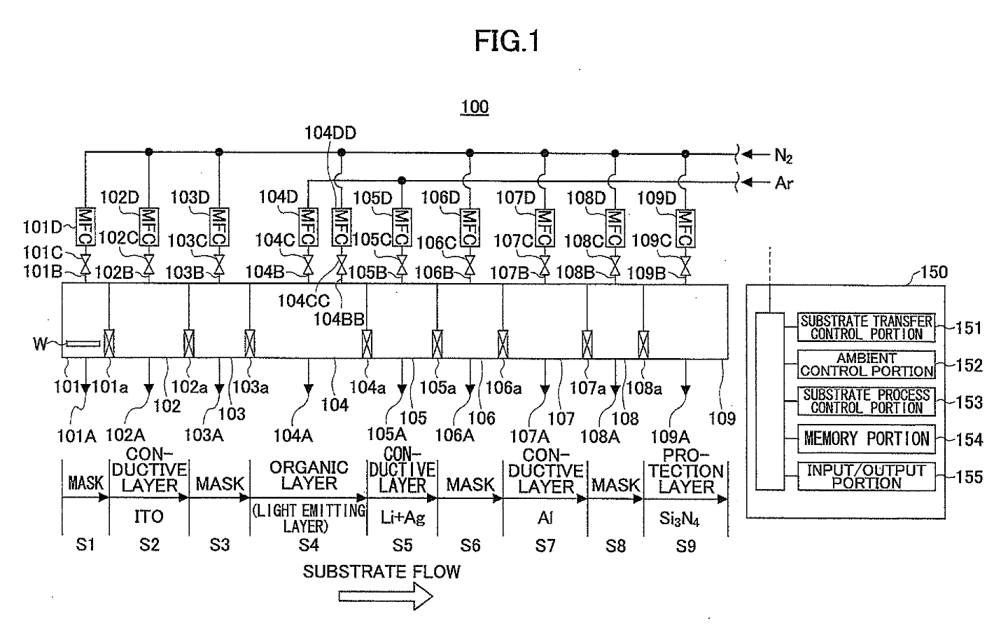

FIG. 1 is a schematic view illustrating a manufacturing apparatus 100 according to Example 1 of the present invention. Referring to FIG. 1t the manufacturing apparatus 100 according to this example has plurality of process chambers 101 through 109 connected substantially in line. In the drawing, inner structures of the process chambers are not shown.

Gate valves 101a through 108a are provided between corresponding adjacent two of the process chambers 101 through 109. Namely, the gate valve 101a is provided between the process chambers 101, 102; the gate valve 102a is provided between the process chambers 102, 103; the gate valve 103a is provided between the process chambers 103, 104; the gate valve 104a is provided between the process chambers 104, 105; the gate valve 105a is provided between the process chambers 105, 106; the gate valve 106a is provided between the process chambers 106, 107; the gate valve 107a is provided between the process chambers 107, 108; and the gate valve 108a is provided between the process chambers 108, 109.

The manufacturing apparatus 100 has a transfer mechanism such as a transfer arm (not shown) inside of the process chambers 101 through 109. The substrate to be processed is transferred between one process chamber and the adjacent process chamber when the gate valve in-between is open. In this case, the substrate to be processed is transferred substantially in line through the plurality of process chambers, and undergoes a plurality of processes in the corresponding process chambers. In the process apparatus 100 according to this example, the light emitting element having the organic layers of a multilayer structure including the light emitting layer is manufactured through the plurality of processes on the substrate to be processed.

In addition, evacuation lines 101A through 109A connected to evacuation units such as vacuum pumps are connected to the corresponding plural process chambers 101 through 109, so that the insides of the process chambers 101 through 109 are evacuated to a predetermined reduced pressure.

Moreover, gas supplying lines 101B through 109B are connected to the corresponding process chambers 101 through 109, so that the insides of the process chambers 101 through 109 are filled with a predetermined ambient gas. Namely, the insides of the process chambers 101 through 109 may be filled at a predetermined reduced pressure with the ambient gas, when necessary. For example, when the substrate to be processed is transferred between the two process chambers, these two process chambers may be filled at a reduced pressure with the ambient gas.

Valves 101C through 109C and mass flow controllers (MFCs) 101D through 109D are arranged in the corresponding gas supplying lines 101B through 1098, so that a flow rate of the ambient gas is controlled.

A gas supplying line 104BB is connected to the process chamber 104, in addition to the gas supplying line 1048. A valve 104CC and a mass flow controller (MFC) 104DD are arranged in the gas supplying line 104BB, so that a flow rate of the ambient gas is controlled. Namely, either one of two ambient gases (e.g., Ar, N₂) can be selectively supplied to the process chamber 104.

In addition, the manufacturing apparatus 100 has a controller (computer) 150 that controls manufacturing operations in the manufacturing apparatus 100. The controller 150 has a substrate transfer control portion 151 that controls transfer of the substrate to be processed, an ambient control portion 152 that controls the ambient gas supplied to the process chambers 101 through 109, a substrate process control portion 153 that controls substrate processes in the corresponding process chambers 101 through 109, a memory portion 154, and an input/output portion 155.

The operations for manufacturing the light emitting element in the manufacturing apparatus 100 are controlled by the controller 150. In addition, the substrate processes carried out in the corresponding process chambers are controlled by the substrate process control portion 153 in accordance with programs, which may be referred to as recipes, stored in the memory portion 154.

The manufacturing apparatus 100 according to this example is configured to include the plurality of process chambers 101 through 109 connected substantially in line so that the substrate to be processed is transferred in series to the plurality of process chambers 101 through 109, thereby manufacturing the light emitting element.

Namely, the processes are carried out in the corresponding process chambers connected substantially in line so that the plurality of layers including the organic layer are formed on the substrate to be processed in the manufacturing apparatus 100, thereby manufacturing the light emitting element.

Therefore, the manufacturing apparatus 100 has a simplified structure and a small occupying space (footprint), compared with a related art cluster type manufacturing apparatus. In addition, the manufacturing apparatus 100 according to this example provides a simplified transfer route and a simplified transfer system because the substrate to be processed is transferred substantially in line.

Moreover, the manufacturing apparatus 100 according to this example is configured so that the substrate to be processed transferred to the process chambers 101 through 109 is not exposed to oxygen or water. When manufacturing the light emitting element on the substrate to be processed, it is preferable to avoid exposure of oxygen and water to the substrate to be processed. The organic layer such as the light emitting layer (organic EL layer), for example, is easily affected by oxygen and water that can change its properties, which may lead to impaired quality of the light emitting element.

Therefore, the manufacturing apparatus 100 according to this example is configured so that the insides of the process chambers 101 through 109 can be filled with the ambient gas. In addition, the ambient gas is preferably un-reactive (or has no reactivity) with the layer (film) on the substrate to be processed. The ambient gases that occupy the process chambers can be changed depending on the layer on the substrate to be processed in the manufacturing apparatus 100 according to this example. Specific examples of changing the ambient gases are described below.

In addition, FIG. 1 shows substrate process steps S1 (indicated by S1, similarly indicated below) through S9 that are carried out in the corresponding process chambers 101 through 109, in parallel with the corresponding process chambers 101 through 109.

First, the substrate to be processed is transferred into the process chamber 101, and then a mask (patterning mask) is attached on the substrate W to be processed at step S1 in the process chamber 101.

Next, the substrate W to be processed is transferred from the process chamber 101 to the process chamber 102. In this case, the process chambers 101, 102 are preferably filled with, for example, nitrogen (N₂) gas at a reduced pressure. The substrate W to be processed is transferred from the process chamber 101 to the process chamber 102 by a transfer arm (not shown) after the gate valve 101a is opened.

Then, the positive electrode made of, for example, Indium Tin Oxide (ITO) is formed into a predetermined pattern on the substrate W to be processed at step S2 (in the process chamber 102). The process chamber 102 is configured so that the positive electrode can be formed by, for example, a CVD (chemical vapor deposition) method. However, the process chamber 102 may be configured so that the positive electrode can be formed by, for example, a sputtering method.

Next, the substrate W to be processed is transferred from the process chamber 102 to the process chamber 103. In this case, the process chambers 102, 103 are preferably filled with, for example, nitrogen (N₂) gas at a reduced pressure. The substrate W to be processed is transferred from the process chamber 102 to the process chamber 103 by the transfer arm (not shown) after the gate valve 102a is opened.

Next, the mask that has been attached on the substrate W to be processed is removed and another mask is attached on the substrate W to be processed, when necessary, at step S3 (in the process chamber 103).

Next, the substrate W to be processed is transferred from the process chamber 103 to the process chamber 104. In this case, the process chambers 103, 104 are preferably filled with, for example, nitrogen (N₂) gas at a reduced pressure. The substrate W to be processed is transferred from the process chamber 103 to the process chamber 104 by the transfer arm (not shown) after the gate valve 103a is opened.

Next, the organic layer of the multilayer structure including the light emitting layer (organic EL layer) is formed by, for example, an evaporation process on the substrate W to be processed on which the positive electrode is formed, at step S4 (in the process chamber 104). In this case, the process chamber 104 is configured to have a plurality of film source supplying portions in order that the multilayer structure is formed in series by the evaporation process. Such a configuration is described below.

Next, the substrate W to be processed is transferred from the process chamber 104 to the process chamber 105. In this case, the process chambers 104, 105 are preferably filled with an ambient gas at a reduced pressure. The substrate W to be processed is transferred from the process chamber 104 to the process chamber 105 by the transfer arm (not shown) after the gate valve 104a is opened.

In this case, the ambient gas is preferably un-reactive (or has no reactivity) with a work function adjusting layer formed at the next step S5 (in the process chamber 105). In this case, the work function adjusting layer is to improve emission efficiency of the organic layer. For example, when the work function difference between the organic layer and the negative electrode is too large, a problem is raised in that the emission efficiency of the light emitting element is reduced. Therefore, it is preferable to provide the work function adjusting layer between the organic layer and the negative electrode in order to adjust the work function, thereby suppressing a reduction of the emission efficiency of the light emitting element

For example, the work function adjusting layer is formed of an active metal such as alkali metal (e.g., lithium (Li)). The alkali metal may be reacted with, for example, the ambient gas to form a compound. For example, Li may be azotized when nitrogen exists in the ambient atmosphere.

Therefore, it is preferable that the process chambers 104, 105 are filled at a reduced pressure with a noble gas (e.g., argon (Ar) gas), which is un-reactive with the work function adjusting layer. The manufacturing apparatus 100 according to this example is configured so that the ambient gas at the time of transferring the substrate to be processed can be changed depending on materials of the layers formed on the substrate to be processed. Therefore, when the active layer such as the work function adjusting layer is formed, a noble gas such as Helium (He), Neon (Ne), Ar, Krypton (Kr), and Xenon (Xe) is preferably used as the ambient gas. In addition, when the exposed layer on the substrate to be processed is ITO, Aluminum (Al), Silver (Ag), and the like, it is preferable that the ambient gases are changed to an inexpensive gas such as nitrogen gas.

Next, the work function adjusting layer made of Li is formed on the organic layer by the evaporation process at step S5 (in the process chamber 105), and an Ag layer that constitutes a part of the negative electrode is formed on the work function adjusting layer by the sputtering method. The process chamber 105 so configured is described below.

Next, the substrate W to be processed is transferred from the process chamber 105 to the process chamber 106. In this case, because the work function adjusting layer (Li layer) is covered with the Ag layer, the process chambers 105, 106 may be filled with the nitrogen (N₂) gas at a reduced pressure. The substrate W to be processed is transferred from the process chamber 105 to the process chamber 106 by the transfer arm (not shown) after the gate valve 105a is opened.

Next, the mask that has been attached on the substrate W to be processed is removed and another mask is attached on the substrate W to be processed, when necessary, at step S6 (in the process chamber 106).

Next, the substrate W to be processed is transferred from the process chamber 106 to the process chamber 107. In this case, the process chambers 106, 107 are preferably filled with, for example, the nitrogen (N₂) gas at a reduced pressure. The substrate W to be processed is transferred from the process chamber 106 to the process chamber 107 by the transfer arm (not shown) after the gate valve 106a is opened.

Next, an Al layer is formed into a predetermined pattern by, for example, the sputtering method at step S7 (in the process chamber 107). With this, the negative electrode made of the Ag layer and the Al layer is formed.

Next, the substrate W to be processed is transferred from the process chamber 107 to the process chamber 108. In this case, the process chambers 107, 108 are preferably filled with, for example, the nitrogen (N₂) gas at a reduced pressure. The substrate W to be processed is transferred from the process chamber 107 to the process chamber 108 by the transfer arm (not shown) after the gate valve 107a is opened.

Next, the mask that has been attached on the substrate W to be processed is removed and another mask is attached on the substrate W to be processed, when necessary, at step S8 (in the process chamber 108).

Next, the organic layer and the electrodes are covered with an insulation layer made of silicon nitride (Si₃N₄) and the like by, for example, the CVD method, and thus the light emitting element is completed (at step 39 in the process chamber 109).

According to the manufacturing apparatus 100 for the light emitting element, an ambient pressure can be adjusted for different process chambers when the substrate W to be processed is transferred, which makes it possible to suppress contamination caused in one process chamber reaching an adjacent process chamber.

For example, the ambient gas can flow in a preferable direction by providing a pressure difference between the adjacent two process chambers.

Specifically, it is possible to suppress interfusion of the metals (Li, Al and the like) at the time of forming the organic layer by setting a pressure in the process chamber 104 higher than a pressure in the process chamber 105.

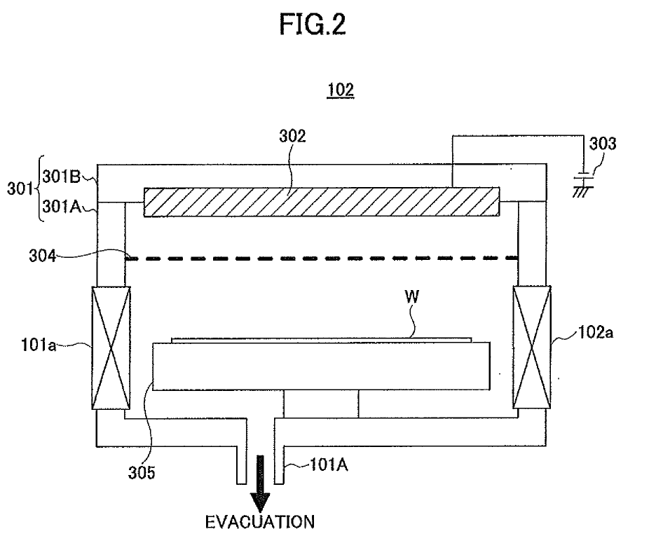

Next, configuration examples of the process chamber of the manufacturing apparatus 100 are described in reference to FIGS. 2 through 5. In FIGS. 2 through 5, like reference symbols are given to portions described above, and repetitive explanation is omitted.

FIG. 2 is a schematic cross-sectional view of the process chamber 102 shown in FIG. 1. The gas supplying line 102B is omitted in this drawing.

Referring to FIG. 2, the process chamber 102 has a process vessel 301, inside of which a holding pedestal 305 that holds the substrate W to be processed is arranged. The process vessel 301 is configured of a bottom vessel 301A having, for example, a substantially cylindrical shape and a lid portion 301B placed on one end opening of the bottom vessel 301A. A substantially disk-shaped antenna 302 is arranged in the lid portion 301B. Microwaves are applied to the antenna 302 from an electric power supply 303.

In addition, a gas supplying portion 304 for supplying a film source gas for forming the film to the process vessel 301 is arranged between the antenna 302 and the holding pedestal 305. The gas supplying portion 304 is formed into, for example, a lattice-like and thus the microwaves can pass through the gas supplying portion 304.

With this, the film source gas supplied from the gas supplying portion 304 is excited into plasma by the microwaves supplied from the antenna 302, and the excited film source gas is adsorbed on the substrate W to be processed. With this, the positive electrode (transparent electrode) made of, for example, ITO is formed.

In addition, the process chamber for forming the negative electrode may be configured so that the sputtering method can be carried out, instead of the CVD method.

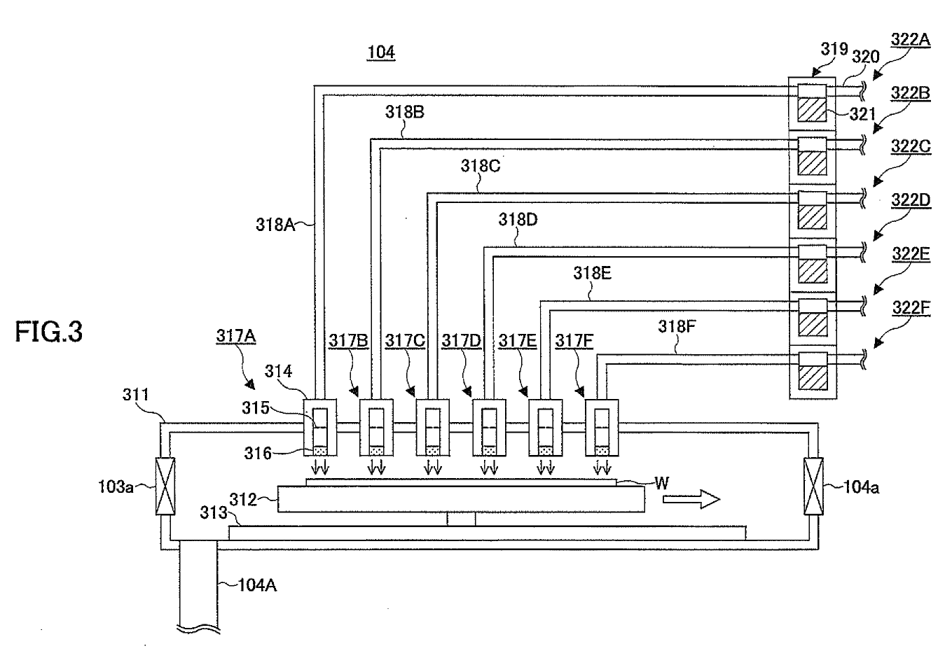

FIG. 3 is a schematic cross-sectional view showing the process chamber 104 of FIG. 1. In this drawing, the gas supplying line 104B is omitted. Referring to FIG. 3, the process chamber 104 has a process vessel 311 having in its inside a holding pedestal 312 that supports the substrate W to be processed.

Outside of the process vessel 311, a gaseous source generation portion 322A is arranged that evaporates or sublimates a liquid or solid film source 321 to generate a film source gas (gaseous source).

The gaseous source generation portion 322A has a source container 319 and a carrier-gas supplying line 320. The film source 321 stored in the source container 319 is heated by a heater (not shown) and thus the film source gas (gaseous source) is generated. The generated film source gas is transported to the gas supplying portion 317A arranged in the process vessel 311 through a transport conduit 318A along with a carrier gas supplied from the carrier gas supplying line 320. Then, the film source gas is supplied from the film source gas supplying portion 317A to a space in the process vessel 311 above the substrate W to be processed, is decomposed near and/or on the substrate W to be processed, and thus a film is deposited on the substrate W to be processed.

The gas supplying portion 317A has a supplying portion body 314 having, for example, a cylindrical or chassis-like shape, to which the transport conduit 318A is connected. One end of the supplying portion body 314 is open toward the substrate W to be processed. In this open end, a filter plate 316 is arranged that is formed of, for example, a porous metal material (metal filter). In addition, inside of the supplying portion body 314, a flow controlling plate 315 is arranged that controls the flow of the film source gas.

In the process vessel 311, gas supplying portions 3173 through 317F having the same configuration as the gas supplying portion 317A are aligned in line along with the gas supplying portion 317A. The gas supplying portions 317B through 317F are connected to corresponding gaseous source generation portions 322B through 322F through corresponding transport conduits 318B through 318F. The gaseous source generation portions 3223 through 322F have the same configuration as the gaseous source generation portion 322A.

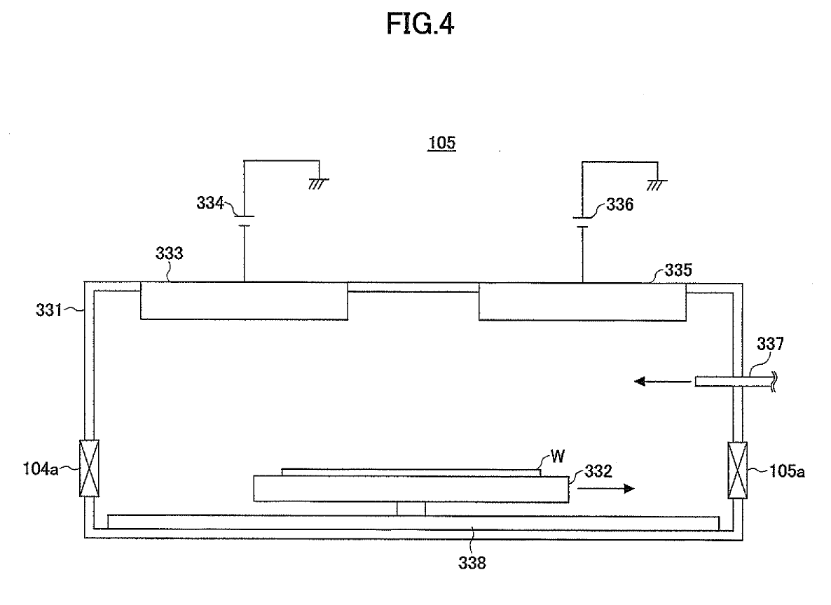

In addition, a transfer rail 313 is provided on a bottom surface of the process vessel 311, and the holding pedestal 312 is arranged to move along the transfer rail 313. When the holding pedestal 312 moves in a direction indicated by an arrow in FIG. 4, the substrate W to be processed placed on the holding pedestal 312 passes below the gas supplying portions 317A through 317F in this order.

In this case, because different film source gases are supplied from the corresponding gas supplying portions 317A through 317F and the holding pedestal 312 is moved, the organic layer of the multilayer structure is formed on the substrate W to be processed in a face-up manner.

The organic layer of the multilayer structure is formed in the plurality of process chambers even in a related art manufacturing apparatus of the cluster structure. Therefore, many process chambers are required in order to form the organic layer, which causes disadvantages in that such an apparatus tends to be large and complicated. According to the manufacturing apparatus of this example of the present invention, the organic layer of the multilayer structure can be formed sequentially in one process chamber. Therefore, the manufacturing apparatus can be structurally simplified and easily downsized. Moreover, the substantially linear alignment of the process chambers can be easily realized.

FIG. 4 is a schematic cross-sectional view of the process chamber 105 of FIG. 1. In the drawing, the gas supplying line 105B and the evacuation line 105A are omitted. Referring to FIG. 4, the process chamber 105 has a process vessel 331 having in its inside a holding pedestal 332 that holds the substrate W to be processed. The holding pedestal 332 is configured to be movable in parallel on a transfer rail 338 arranged on a bottom surface of the process vessel 331.

In the process vessel 331, targets 333, 335 are arranged to oppose the holding pedestal 332. The targets 333, 335 are connected to corresponding electric power supplies 334, 336. In addition, a gas supplying portion 337 that supplies a gas for sputtering, such as Ar, is arranged through a side wall of the process vessel 331.

In the process chamber 105, different layers made of different materials (e.g., the work function adjusting layer and the negative electrode) can be formed in series. In addition, when the Ag layer is formed in series by the sputtering method after the Li layer, for example, is formed by the evaporation process, the configuration (the transport configuration for transporting the film source gas for evaporation) shown in FIG. 3 should be added to the process chamber 105. For example, structures corresponding to the gaseous source generation portion 322A, the transport conduit 318A, and the gas supplying portion 317A should be added to the process chamber 105 shown in FIG. 3, so that the film source gas (gaseous source) for Li is transported and deposited.

In forming a film by, for example, the sputtering method, damage caused on an object on which the film is formed can be suppressed by arranging two targets in parallel.

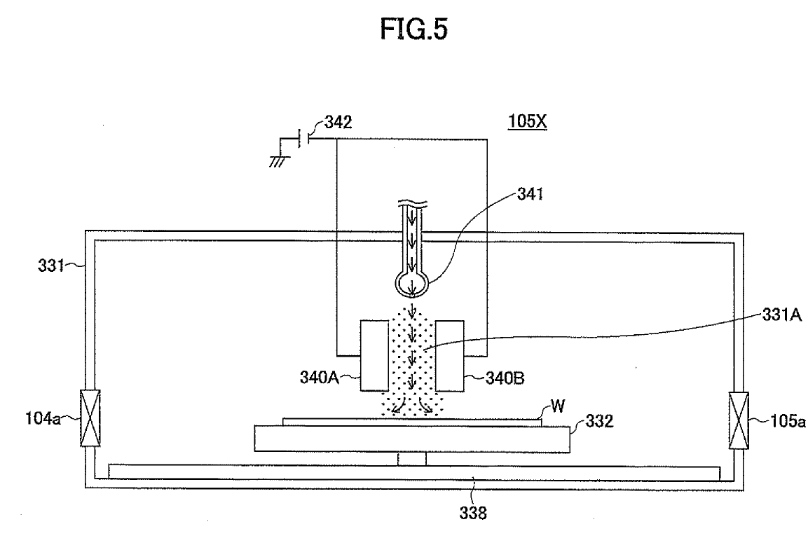

FIG. 5 is a configuration example of a process chamber 105X that may be employed in the manufacturing apparatus 100. In the drawing, like reference symbols are given to the portions described above, and explanation about such portions is omitted. Referring to FIG. 5, targets 340A, 340B across which voltage is applied are arranged to oppose each other above the substrate holding pedestal 332 inside the process vessel 331 of the process chamber 105X.

The two targets 340A, 340B extend in a direction substantially perpendicular to the direction along which the substrate holding pedestal 332 moves, and are arranged to oppose each other.

In addition, a gas supplying portion 341 for supplying a process gas for the sputtering such as Ar is arranged in a space 331A between the targets 340A, 340B in the process vessel 331. The process gas is excited into plasma by applying the voltage across the targets 340A, 340B from an electric power source 342.

In the process chamber 105X, electric power is applied to the targets 340A, 340B from the electric power source 342, so that plasma is generated in the space 331A and the targets 340A, 340B are sputtered, thereby forming a film on the substrate W to be processed.

In the process chamber 105X, the substrate W to be processed is away from the space where the plasma is excited, and thus the film to be formed is not susceptible to damage by ultraviolet light caused by the plasma excitation or bombardment of sputtered particles.

In addition, a structure that combines the targets 340A, 340B and the gas supplying portion 341 may be provided in order to form the multilayer structure by the sputtering.

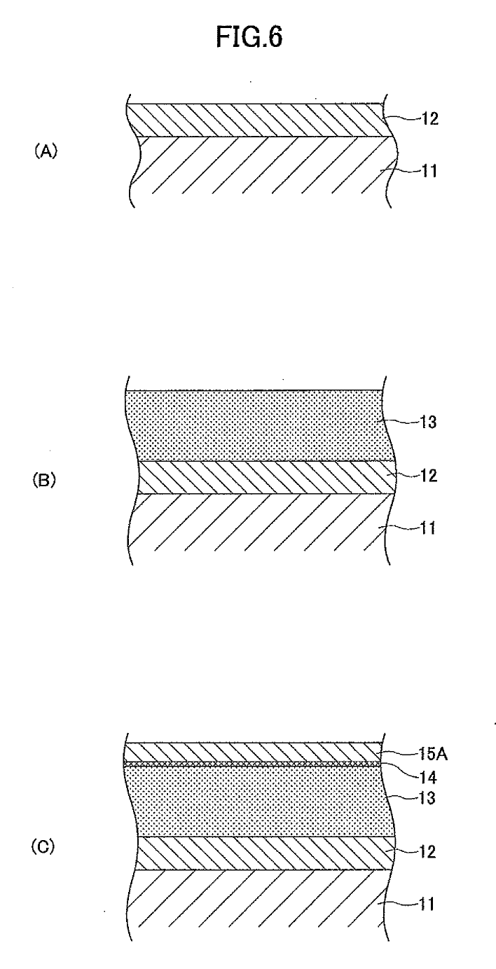

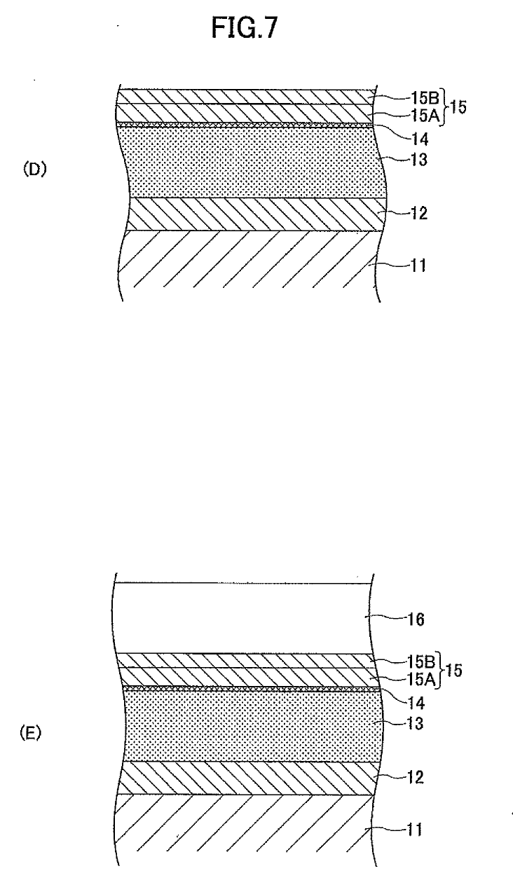

Next, an example of manufacturing the light emitting element using the manufacturing apparatus 100 for the light emitting element is described process by process in reference to FIGS. 6(A) through 6(C) and FIGS. 7(D) through 7(E).

FIG. 6(A) is a view illustrating a process corresponding to step S2 of FIG. 1. In this process, a positive electrode 12 made of, for example, ITO is formed on a substrate 11, which corresponds to the substrate W to be processed, for example, in the process chamber 102 shown in FIG. 2.

FIG. 6(B) is a view illustrating a process corresponding to step 84 of FIG. 1. In this process, an organic layer 13 having the multilayer structure including the light emitting layer (organic EL layer) is formed on the positive electrode 12, for example, in the process chamber 104 shown in FIG. 3. For example, the organic layer 13 is formed by accumulating a hole injection layer, a hole transport layer, the light emitting layer (organic EL layer), an electron transport layer, and an electron injection layer on the positive electrode 12 in this order. In addition, the hole injection layer, the hole transport layer, the electron transport layer, and the electron injection layer may be omitted depending on circumstances. Moreover, the organic layer 13 is not limited to this structure, and hence various configurations are possible.

FIG. 6(C) is a view illustrating a process corresponding to step S5 of FIG. 1. In this process, first, a work function adjusting layer 14 made of a Li layer is formed on the organic layer 13 by, for example, the sputtering method, and then an Ag layer 15A that constitutes the negative electrode is formed on the work function adjusting layer 14.

The sputtering in this case is preferable when carried out in the process chamber having the two targets that oppose each other, because damage on the underlying layer (e.g., the organic layer 13) can be suppressed.

FIG. 7(D) is a view illustrating a process corresponding to step S7 of FIG. 1. In this process, an Al layer 15B is formed on the Ag layer 15A by, for example, the sputtering method, so that the negative electrode 15 formed of the Ag layer 15A and the Al layer 15B is formed,

FIG. 7(E) is a view illustrating a process corresponding to step S9 of FIG. 1. In this process, a protection layer 16 made of Si₃N₄ is formed to cover the negative electrode 15 by the CVD method, for example, in the process chamber 109 having the same configuration as the process chamber 102 shown in FIG. 2.

In such a manner, the light emitting element having the organic layer (organic EL layer) between the positive electrode 12 and the negative electrode 15 can be manufactured. The light emitting element having such a structure may be referred to as a bottom emission type (top cathode type) light emitting element.

In the bottom emission type light emitting element, because the negative electrode 15 provides a function of reflecting light, the negative electrode 15 is preferably configured of Ag, which is a material with high reflectivity. In addition, when Ag is used for the negative electrode 15, Li is preferably used as the work function adjusting layer between the Ag layer and the organic layer in order to realize high emission efficiency.

### Example 2

The manufacturing apparatus 100 according to Example 1 is to manufacture a bottom emission type light emitting element but may also be applied to manufacturing a top emission type light emitting element.

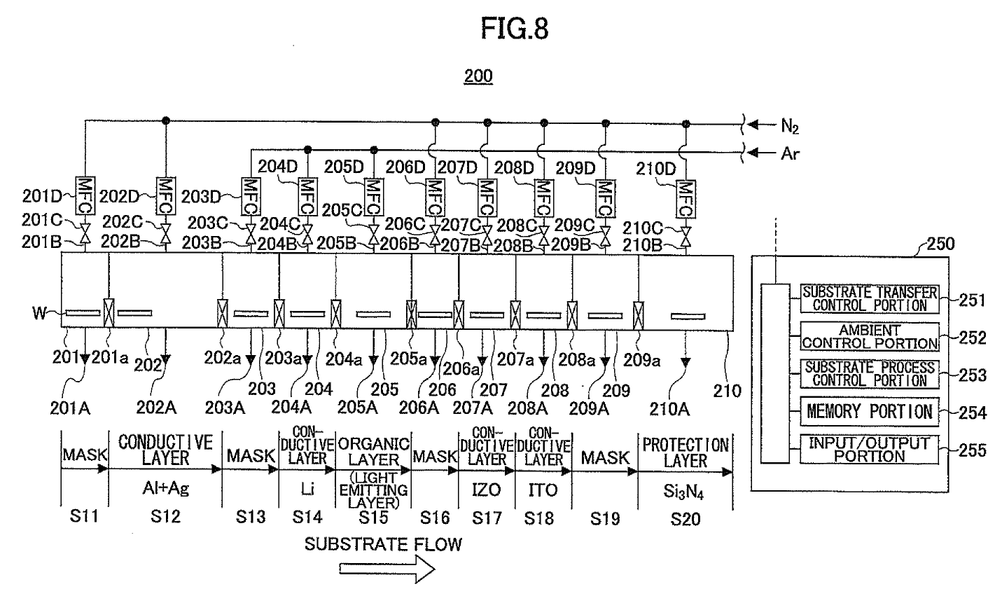

FIG. 8 is a schematic view illustrating a manufacturing apparatus 200 for the light emitting element. The manufacturing apparatus 200 for the light emitting element, according to this example is the same as the manufacturing apparatus 100 according to Example 1 in terms of the basic structure and operations, and provides the same effect as Example 1.

Referring to FIG. 8, the manufacturing apparatus 200 according to this example is configured so that plurality of process chambers 201 through 210 are connected substantially in line. In the drawing, inner structures of the process chambers are omitted. Gate valves 201a through 209a are provided between the adjacent two process chambers.

The manufacturing apparatus 200 according to this example is the same as Example 1 in that the manufacturing apparatus 200 has a transfer unit such as a transfer arm (not shown) and is configured so that the substrate W to be processed is transferred between the adjacent two process chambers when the gate valve is open. In this case, the substrate to be processed is transferred substantially in line through the plurality of process chambers, and substrate processes are carried out in the corresponding process chambers, thereby manufacturing the light emitting element having an organic layer of the multilayer structure including the light emitting layer on the substrate to be processed.

In addition, the process chambers 201 through 210 are configured in the same manner as Example 1 in that the insides of the process chambers may be filled with the ambient gas at a reduced pressure, for example, when the substrate to be processed is transferred.

For example, evacuation lines 201A through 210A that are connected to evacuation units such as vacuum pumps are connected to the corresponding plural process chambers 201 through 210, so that the insides of the process chambers 201 through 210 are evacuated to a predetermined reduced pressure.

In addition, gas supplying lines 201B through 210B are connected to the corresponding process chambers 201 through 210, so that the insides of the process chambers 201 through 210 are filled with a predetermined ambient gas. Moreover, valves 201C through 210C and mass flow controllers (MFCs) 201D through 210D are provided in the gas supplying lines 201B through 210B, so that a flow rate of the supplied ambient gas is controlled.

In addition, the manufacturing apparatus 200 has a controller (computer) 250 that has the same functions as the controller 150 of Example 1. The controller 250 has a substrate transfer control portion 251 that controls transfer of the substrate to be processed, an ambient control portion 252 that controls the ambient gas supplied to the process chambers 201 through 210, a substrate process control portion 253 that controls substrate processes in the corresponding process chambers 201 through 210, a memory portion 254, and an input/output portion 255.

In addition, FIG. 8 shows substrate process steps S11 through S20 that are carried out in the corresponding process chambers 201 through 210, in parallel with the corresponding process chambers 201 through 210

First, when the substrate W to be processed is transferred into the process chamber 201, a mask (patterning mask) is attached on the substrate W to be processed at step S11.

Next, the substrate W to be processed is transferred from the process chamber 201 to the process chamber 202. In this case, the process chambers 201, 202 are preferably filled with, for example, nitrogen (N₂) gas at a reduced pressure. The substrate W to be processed is transferred by a transfer arm (not shown) from the process chamber 201 to the process chamber 202 after the gate valve 201a is opened.

Next, the negative electrode made of the Al layer and the Ag layer is formed on the substrate W to be processed, by, for example, the sputtering method at step S12 (in the process chamber 202).

Next, the substrate W to be processed is transferred from the process chamber 202 to the process chamber 203. In this case, the process chambers 202, 203 are preferably filled with, for example, nitrogen (N₂) gas at a reduced pressure. The substrate W to be processed is transferred by the transfer arm (not shown) from the process chamber 202 to the process chamber 203 after the gate valve 202a is opened.

Next, the mask that has been attached on the substrate W to be processed is removed and another mask is attached on the substrate W to be processed when necessary at step S13 (in the process chamber 203).

Next, the substrate W to be processed is transferred from the process chamber 203 to the process chamber 204. In this case, the process chambers 203, 204 are preferably filled with, for example, an ambient gas at a reduced pressure. The substrate W to be processed is transferred by the transfer arm (not shown) from the process chamber 203 to the process chamber 204 after the gate valve 203a is opened.

In this case, it is preferable that the ambient gas is substantially un-reactive (has no reactivity) with a work function adjusting layer to be formed at the next step S14 (in the process chamber 204).

For example, the work function adjusting layer is formed of an active metal such as alkali metal (e.g., Li). The alkali metal may be reacted with, for example, the ambient gas to form a compound. For example, Li may be azotized when nitrogen exists in the ambient atmosphere.

Therefore, it is preferable that the process chambers 203, 204 are filled at a reduced pressure with a noble gas (e.g., Ar gas), which is un-reactive with the work function adjusting layer. The manufacturing apparatus 200 (manufacturing method) according to this example is configured so that the ambient gas at the time of transferring the substrate to be processed can be changed depending on materials of the layers formed on the substrate to be processed, in the same manner as Example 1. When the active layer such as the work function adjusting layer is formed, a noble gas such as He, Ne, Ar, Kr, and Xe is preferably used as the ambient gas. In addition, when the exposed layer on the substrate to be processed is ITO, Aluminum (Al), Silver (Ag) and the like, it is preferable that the ambient gases are changed to an inexpensive gas such as nitrogen gas.

Next, the work function adjusting layer made of the Li layer is formed on the substrate W to be processed on which the negative electrode is formed, at step S14 (in the process chamber 204).

Next, the substrate W to be processed is transferred from the process chamber 204 to the process chamber 205. In this case, the process chambers 204, 205 are preferably filled at a reduced pressure with the ambient gas (e.g., noble gases such as He, Ne, Ar, Kr, and Xe) that is not reacted with the work function adjusting layer. The substrate W to be processed is transferred by the transfer arm (not shown) from the process chamber 204 to the process chamber 205 after the gate valve 204a is opened.

Next, the organic layer of the multilayer structure including the light emitting layer (organic EL layer) is formed by, for example, the evaporation process on the substrate W to be processed on which the negative electrode and the work function adjusting layer are formed, at step S15 (in the process chamber 205).

Next, the substrate W to be processed is transferred from the process chamber 205 to the process chamber 206. In this case, because the work function adjusting layer (Li layer) is covered with the organic layer, the process chambers 205, 206 are preferably filled with, for example, nitrogen (N₂) gas at a reduced pressure. The substrate W to be processed is transferred by the transfer arm (not shown) from the process chamber 205 to the process chamber 206 after the gate valve 205a is opened.

Next, the mask that has been attached on the substrate W to be processed is removed, and another mask is attached on the substrate W to be processed when necessary, at step S16 (in the process chamber 206).

Next, the substrate W to be processed is transferred from the process chamber 206 to the process chamber 207. In this case, the process chambers 206, 207 are preferably filled with, for example, nitrogen (N₂) gas at a reduced pressure. The substrate W to be processed is transferred by the transfer arm (not shown) from the process chamber 206 to the process chamber 207 after the gate valve 206a is opened.

Next, Indium Zinc Oxide (IZO) constituting a positive electrode having a predetermined pattern is formed by, for example, the sputtering method using the mask at step S17 (in the process chamber 207).

Next, the substrate W to be processed is transferred from the process chamber 207 to the process chamber 208. In this case, the process chambers 207, 208 are preferably filled with, for example, nitrogen (N₂) gas at a reduced pressure. The substrate W to be processed is transferred by the transfer arm (not shown) from the process chamber 207 to the process chamber 208 after the gate valve 207a is opened.

Next, an ITO layer that constitutes the positive electrode and has the same pattern as the IZO layer is formed at step S18 (in the process chamber 208) by, for example, the sputtering method using the same mask as used at step S17. With this, the positive electrode (transparent electrode) made of the IZO layer and the ITO layer is formed.

Next, the substrate W to be processed is transferred from the process chamber 208 to the process chamber 209. In this case, the process chambers 208, 209 are preferably filled with, for example, nitrogen (N₂) gas at a reduced pressure. The substrate W to be processed is transferred by the transfer arm (not shown) from the process chamber 208 to the process chamber 209 after the gate valve 208a is opened.

Next, the mask that has been attached on the substrate W to be processed is removed, and another mask is attached on the substrate W to be processed when necessary, at step S19 (in the process chamber 209).

Next, an insulating layer made of Si₃N₄ and the like is formed to cover the organic layer and the electrode by, for example, the CVD method at step S20 (in the process chamber 210), and thus the light emitting element is completed.

Next, an example of manufacturing the light emitting element using the manufacturing apparatus 200 for the light emitting element is described process by process in reference to FIGS. 9(A), 9(B), FIGS. 10(D) through 7(E), and FIGS. 11(E) through 11(F).

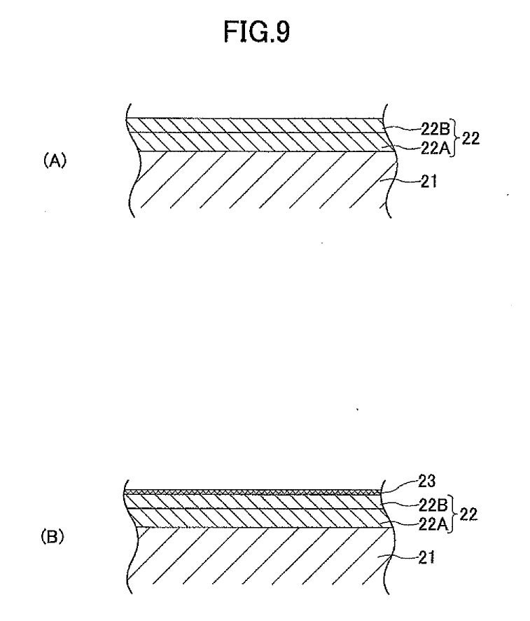

FIG. 9(A) is a view illustrating a process corresponding to step S12 of FIG. 8. In this process, an Al layer 22A and an Ag layer 22B are formed in series on a substrate, which corresponds to the substrate W to be processed, by the sputtering method, for example, in the process chamber 202 having the same configuration as the process chamber 105 shown in FIG. 4. With this, a negative electrode 22 made of the Al layer 22A and the Ag layer 22B is formed,

FIG. 9(B) is a view illustrating a process corresponding to step S14 of FIG. 5. In this process, a work function adjusting layer 23 made of a Li layer is formed on the negative electrode 22 by, for example, the evaporation process in the process chamber 204.

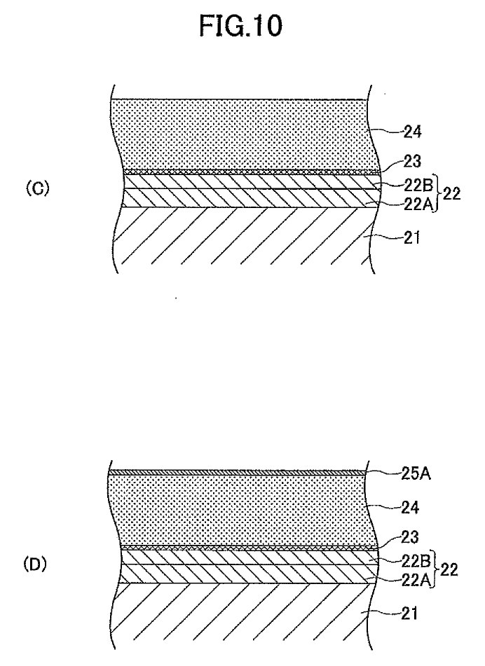

FIG. 10(C) is a view illustrating a process corresponding to step S15 of FIG. B. In this process, an organic layer 24 having a multilayer structure including a light emitting layer (organic EL layer) is formed on the work function adjusting layer 23 in the process chamber 205 having the same configuration as the process chamber 204 shown in FIG. 3. For example, the organic layer 24 is formed by accumulating an electron injection layer, an electron transport layer, the light emitting layer (organic EL layer) a hole transport layer, and a hole injection layer on the work function adjusting layer 23 in this order. In addition, the electron injection layer, the electron transport layer, the hole transport layer, and the hole injection layer may be omitted depending on circumstances. Moreover, the organic layer is not limited to the above structure, and hence various configurations are possible.

FIG. 10(D) is a view illustrating a process corresponding to step S17 of FIG. 8. In this process, an IZO layer 25A constituting a positive electrode is formed on the organic layer 24 by, for example, the sputtering method in the process chamber 207.

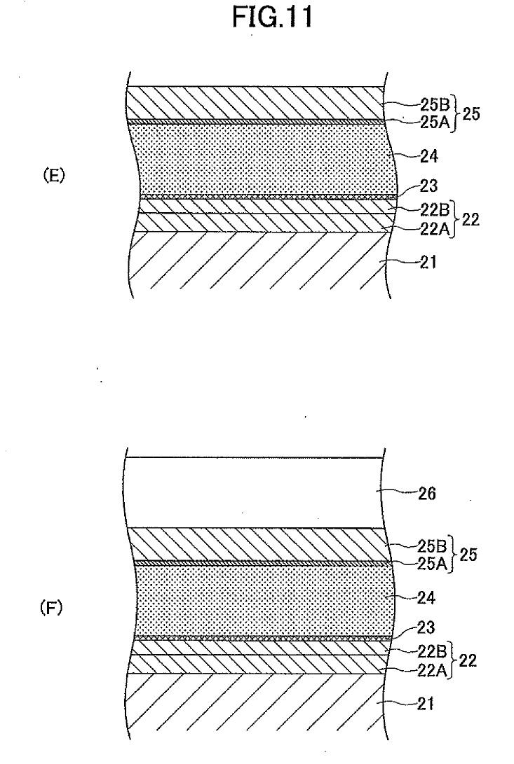

FIG. 11(E) is a view illustrating a process corresponding to step S18 of FIG. 8. In this process, an ITO layer 25B is formed on the IZO layer 25A by, for example, the sputtering method in the process chamber 208. With this, the positive electrode 25 made of the IZO layer 25A and the ITO layer 25B is formed.

FIG. 11(F) is a view illustrating a process corresponding to step 520 of FIG. 8. In this process, a protection layer 26 made of Si₃N₄ is formed to cover the positive electrode 25 by the CVD method in, for example, the process chamber 210 having the same configuration as the process chamber 102 shown in FIG. 2, and thus the light emitting element is completed.

In such a manner, the light emitting element having the organic layer 24 between the negative electrode 22 and the positive electrode 25 can be manufactured. The light emitting element having such a configuration may be referred to as a top emission type light emitting element.

Because the negative electrode 22 has a function of reflecting light in the top emission type light emitting element, the negative electrode 22 is preferably formed of Ag, which is a material having high reflectivity. In addition, when Ag is used in the negative electrode 22, it is preferable that Li is used for the work function adjusting layer between the Ag layer and the organic layer 24 in order to improve emission efficiency.

It is apparent that the present invention is not limited to the above example, but light emitting elements having various structures can be formed in various process chamber configurations.

While the present invention has been described in view of the preferred examples, the present invention is not limited to the above particular examples but can be modified or altered within the scope of the claims.

### INDUSTRIAL APPLICABILITY

According to the present invention, a light emitting element manufacturing apparatus having a simplified structure and a small occupying space and a light emitting element manufacturing method that reduces occupying space can be provided.

This international application claims the benefit of the priority date of Japanese Patent Application No. 2006-164966 filed on Jun. 14, 2006, and the entire content of which application is hereby incorporated by reference.

1. An apparatus for manufacturing a light emitting element having plural layers including an organic layer on a substrate to be processed, the apparatus comprising:
a plurality of process chambers to which said substrate to be processed is transferred in series,
wherein said plurality of process chambers are substantially linearly connected to one another and wherein adjacent two of said process chambers are filled with gas that does not react with a layer on said substrate to be processed when said substrate to be processed is transferred between the two process chambers.

2. The apparatus of claim 1, wherein said gas can be changed depending on a material that constitutes said layer on said substrate to be processed.

3. The apparatus of claim 1, wherein the plurality of process chambers include at least an organic layer forming chamber for forming said organic layer, and an electrode forming chamber for forming an electrode for applying voltage to said organic layer.

4. The apparatus of claim 3, wherein said organic layer includes a multilayer structure having a light emitting layer to which voltage is applied to emit light, and wherein said organic layer forming chamber is configured so that said multilayer structure may be sequentially formed by an evaporation process.

5. The apparatus of claim 4, wherein said organic layer forming chamber is provided with a holding pedestal by which said substrate to be processed is held and a plurality of film source supplying portions that supply a plurality of film sources to said substrate to be processed.

6. The apparatus of claim 5, wherein the plurality of film source holding portions are linearly arranged and said holding pedestal may be moved along the arrangement direction of the plurality of film source supplying portions.

7. The apparatus of claim 4, wherein the plurality of process chambers include an adjusting layer forming chamber, wherein a work function adjusting layer for improving emission efficiency of said light emitting layer is formed between said organic layer and said electrode.

8. The apparatus of claim 7, wherein the work function adjusting layer is formed of an alkali metal.

9. A method of manufacturing a light emitting element, comprising:
a plurality of process steps carried out in series in corresponding plurality of process chambers in order to form the light emitting element on a substrate to be processed, the light emitting element including a plurality of layers including an organic layer,
wherein the plurality of process chambers are substantially linearly connected to one another, and wherein adjacent two of said process chambers are filled with gas that does not react with a layer on said substrate to be processed when said substrate to be processed is transferred between the two process chambers.

10. The method of claim 9, wherein said gas can be changed depending on a material that constitutes said layer on said substrate to be processed.

11. The method of claim 9, wherein the plurality of process steps include at least an organic layer forming step, wherein said organic layer is formed, and an electrode forming step, wherein an electrode for applying voltage to said organic layer is formed.

12. The method of claim 11, wherein said organic layer includes a multilayer structure having a light emitting layer to which voltage is applied to emit light, and wherein said multilayer structure may be sequentially formed by an evaporation process in said organic layer forming step.

13. The method of claim 12, wherein the plurality of process steps include an adjusting layer forming step, wherein a work function adjusting layer for improving emission efficiency of said light emitting layer is formed, between said organic layer forming step and said electrode forming step.

14. The method of claim 13, wherein the work function adjusting layer is formed of an alkali metal.
